(19) United States
(12) Patent Application Publication
(10) Pub. No.: US 2017/0307731 A1
(43) Pub. Date: Oct. 26, 2017

(54) DIGITAL RADIO FREQUENCY MEMORY SYNTHETIC INSTRUMENT

(71) Applicant: Christopher Heagney, Jacksonville, FL (US)

(72) Inventor: Christopher Heagney, Jacksonville, FL (US)

(73) Assignee: United States of America as represented by the Secretary of the Navy, Patuxent River, MD (US)

(21) Appl. No.: 15/490,238

(22) Filed: Apr. 18, 2017

Related U.S. Application Data
(60) Provisional application No. 62/326,370, filed on Apr. 22, 2016.

(51) Int. Cl. G01S 7/40; G01R 31/28

(52) U.S. Cl. CPC G01S 7/4004; G01R 31/2822

(57) ABSTRACT

An apparatus and method for testing equipment is provided. An analog test signal is received by an analog-to-digital converter. The test signal is converted to a digital test signal. The digital test signal is received by a digital processor. The digital test signal is processed and received by a digital memory and a digital-to-analog converter. The processed digital signal is converted to an analog test signal.

### STATEMENT OF GOVERNMENT INTEREST

The invention described herein may be manufactured and used by or for the Government of the United States of America for governmental purposes without payment of any royalties thereon or therefor.

### BACKGROUND

Automated test equipment, which is often integrated into a Consolidated Automated Support System (CASS), uses automation to quickly perform measurements and evaluate the test results of equipment under test. Equipment under test can include electronics, hardware, software, semiconductors, or avionics. In many instances, automated test equipment is a computer operated machine utilizing digital signal processing hardware. The objective of automated test equipment is to confirm whether equipment under test works and to find defects.

Generally, automated test equipment use a station computer to interface between a radio frequency synthesizer and a spectrum analyzer. In many situations, the resulting test has a high latency between signal capture and generation. In some automated test equipment for avionics examples, high latency of the test poses an obstacle. In some instances, such as when testing devices for countermeasure electronic jamming, the latency of the automated test equipment affects the quality of the testing.

### SUMMARY

In general, in one aspect, an apparatus for testing equipment includes a circuit board comprising: an analog-to-digital converter for converting an analog test signal to a digital test signal; a digital processor for detecting the digital test signal frequency; a digital memory for saving and recalling a detected digital test signal frequency; and a digital-to-analog converter for converting the detected digital test signal to an detected analog test signal.

In general, in one aspect, a method for test equipment includes receiving an analog test signal; converting, by the analog-to-digital converter, the analog test signal to a digital test signal; receiving, by a digital processor, the digital test signal; processing, by the digital processor, the digital test signal; storing, by a digital memory, the processed digital test signal; receiving, by an digital-to-analog converter, the processed digital test signal; and converting, by the digital-to-analog converter, the processed digital test signal to a processed analog test signal,

Unless otherwise defined, all technical and scientific terms used herein have the same meaning as commonly understood by one of ordinary skill in the art to which this invention belongs. Other features and advantages will be apparent from the following detailed description.

### DRAWINGS

These and other features, aspects and advantages of the present invention will become better understood with reference to the following description and appended claims, and accompanying drawings wherein:

FIG. 1 is a diagram of an automated test equipment architecture utilizing the digital radio frequency memory synthetic instrument.

### DETAILED DESCRIPTION

Embodiments of the present invention acknowledge significant deficiencies in automated testing equipment, especially concerning avionics. Traditional testing methods, utilizing a computer (e.g., a PC) for processing, have a high latency. The latency affects the accuracy and reliability of resulting tests. For example, when testing a digital radio frequency memory (DRFM)—used in radar jamming—minimizing the latency of radio frequency signal processing is of utmost importance. For example, assume the unit is capable of jamming two wave forms (e.g., type A and type B). The unit generates signal A, the test equipment detects the waveform, processes, and outputs a countermeasure jamming signal. As a result, the unit generates signal B, the test equipment detects the waveform, processes, and outputs a countermeasure jamming signal. In systems where the test equipment has a high latency in processing the signal, the countermeasure jamming signal will not be effective, as the unit is able to switch frequencies faster than the test equipment can process and output a jamming signal. As a result, there is a need for a testing system that can quickly and accurately process test signals.

Embodiments of the present invention improve existing automated test equipment used to test equipment, especially avionics, by generating wideband, low latency radio frequency (RF) signals. The present invention hybrid hardware/software system (i.e., a synthetic instrument) that capitalizes on the functionality of a field programmable gate array (FPGA), which provides reprogrammable interface to support a variety of testing requirements. A synthetic instrument is a concatenation of hardware and software modules, used in combination to emulate a traditional piece of electronic instrumentation. Use of the DRFM synthetic instrument provides testing at sub-millisecond latency. In some embodiments, the DRFM synthetic instrument shows a 20× latency performance improvement over traditional PC processing. As a result, the DRFM synthetic instrument is not a limiting factor in unit testing.

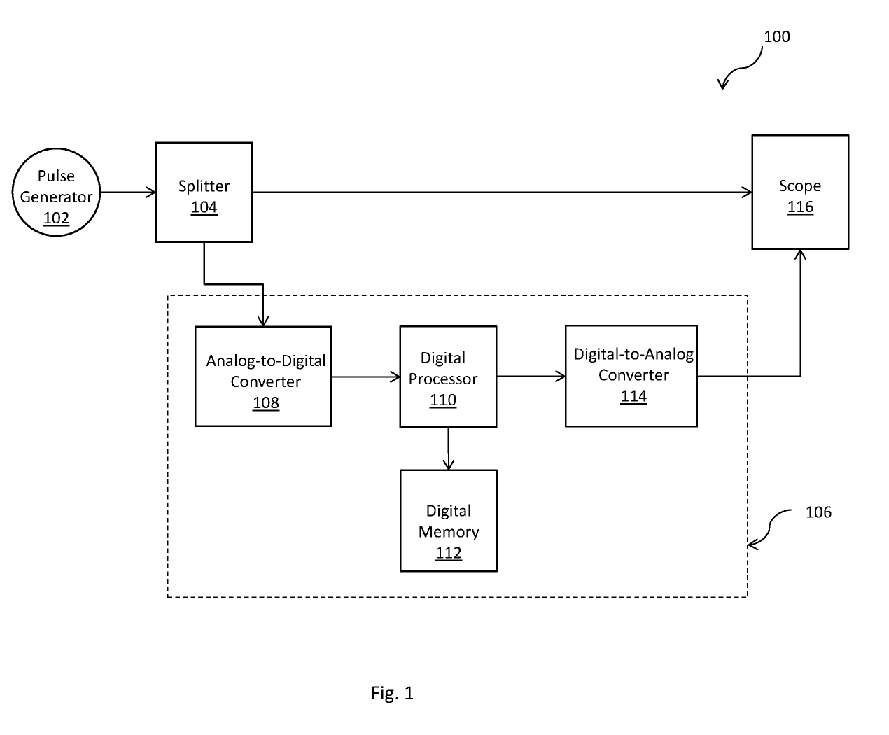

In the following description of the present invention, reference will be made to various embodiments which are not all inclusive. The current invention can be implemented using various forms of software and hardware. However, example embodiments of the present invention are illustrated below and in FIGS. 1 and 2.

FIG. 1 is a diagram of an automated test equipment architecture utilizing the DRFM synthetic instrument. Automated test equipment 100 includes mixer 102, mixer 104, scope 116 and DRFM synthetic instrument 106. The DRFM synthetic instrument 106 produces a test signal. The test signal is an analog signal. The type of signal produced is based on unit being tested. In some embodiments, mixer 104 is optional and is used to up convert a signal into a higher frequency for unit under test 118. Unit under test 118 reacts to the DRFM stimulus and generates a response signal. In some embodiments mixer 102 may be optional and is used to down convert a signal into a lower frequency for the DRFM. A signal splitter splits the unit under test signal, sending one input to DRFM synthetic instrument 106 for processing and another input to scope 116. Scope 116 displays the unit under test response to the DRFM test signal. The delay between the test signal and the response signal is used to determine the latency of the test. In some embodiments, scope 116 is a graphical user interface that displays signal inputs, allowing a technician to analyze the unit under test.

DRFM synthetic instrument 106 has four major components: analog-to-digital converter 108, digital processor 110, digital memory 112, and digital-to analog converter 114. In some embodiments, each of the DRFM synthetic instrument components is embedded on a single circuit board. Having each of the components on a single board allows for the testing equipment to be portable and have a minimal footprint in testing and fabrication environments. In some embodiments, the co-location of the digital electronics on a single circuit board allows for ultra-low latency processing of radio frequency signals in a testing environment.

DRFM synthetic instrument 106 is capable of generating and receiving wideband, low-latency radio frequency signals. The creation and use of a synthetic instrument allows the present invention to support multiple test applications. For example, high speed signal capture, using DRFM synthetic instrument 106, widens instantaneous bandwidth; as a result, testing of frequency-hopping spread spectrum radar, communications, navigation, and identification systems is possible.

Analog-to-digital converter 108 takes an analog signal input and converts it to a digital signal output. By digitizing a signal, the signal can be manipulated (e.g., amplified, modulated, phase shift) without changing the signal fingerprint. In some embodiments, analog-to-digital converter 108 is a high bit resolution component. In some embodiments, analog-to-digital converter 108 is coupled to digital memory 112, allowing accurate capture, storage, and synthesis of a radio signal.

Digital processor 110 is a field programmable gate array. In some embodiments, digital processor 110 may include more than one field programmable gate array. For example, digital processor 110 can be two or more field programmable gate arrays connected in parallel, allowing digital processor 106 to process multiple signals simultaneously. In some embodiments, digital processor 110 is reprogrammed for each test program set. For example, digital processor 110 may require one program to test a countermeasure system and another program to test a radar system. In this example, digital processor 110 can be loaded with the countermeasure testing program while a technician is testing the countermeasure system and can be loaded with the radar testing program while a technician is testing the radar system.

Digital memory 112 is utilized to record signals processed by digital processor 110. In some embodiments, digital memory 112 is high capacity random access memory (RAM). Signals stored in digital memory 112 can be used for faster recall during unit testing.

Digital-to-analog converter 114 takes the processed digital signal as an input and converts it to an analog signal output. In some embodiments, digital-to-analog converter 114 is a high bit resolution component. In some embodiments, digital-to-analog converter 114 is coupled to digital memory 112, allowing rapid synthesis and retrieval of a radio signal.

In some embodiments, the DRFM synthetic instrument 106 can be coupled with a CASS family of testers. In one embodiment, a simple two tone radio frequency test was developed to simulate a jamming technique. DRFM synthetic instrument 106 inputs an arbitrary signal (e.g., 84 MHz) into the unit under test. Once the unit under test detects the signal, it responds by jamming the signal at the measured frequency. DRFM synthetic instrument 106 detects the jamming signal and immediately switches to a second frequency (e.g., 196 MHz). Again, the unit under test detects the signal and responds by jamming at new frequency. This repeats as fast as the unit under test can switch. Speed of the DRFM synthetic instrument 106 is not the limiting factor because it has already been shown to have sub-millisecond latency.

Digital processor 110 is programmed with unique software modules to achieve desired results of the DRFM. In some embodiments, digital processor 110 generates digital values used to create sine waves. Sine tables are created in real-time using a unique algorithm to calculate values on demand. Integers and real numbers are used instead of floating point numbers due to well-known limitations with FPGA place and route synthesizers.

The above description is that of current embodiments of the invention. Various alterations and changes can be made without departing from the spirit and broader aspects of the invention as defined in the appended claims.

What is claimed is:

1. An apparatus for testing equipment, wherein the apparatus comprises:
a circuit board comprising:
an analog-to-digital converter for converting an analog test signal to a digital test signal;
a digital processor for detecting a frequency of the digital test signal and generating a digital test signal having a frequency;
a digital memory for saving and recalling a detected digital test signal frequency and a generated digital test frequencies; and
a digital-to-analog converter for converting the generated digital test signal to a generated analog test signal and converting the detected digital test signal to an detected analog test signal.

2. The apparatus of claim 1, further comprising a scope, wherein the scope displays the detected analog test signal for determining a latency.

3. The apparatus of claim 1, further comprising a scope, wherein the scope measures the detected analog test signal for determining a latency.

4. The apparatus of claim 1, wherein the digital processor is wired to receive an input from the analog-to-digital converter.

5. The apparatus of claim 1, wherein the digital memory receives an input from the digital processor.

6. The apparatus of claim 1, wherein the digital memory stores processed signals for rapid recall.

7. The apparatus of claim 1, wherein the digital-to-analog converter receives an input from the digital processor.

8. The apparatus of claim 1, wherein the digital processor is rapidly programmed to generate the digital test signals and receives one or more signals based on at least one test requirement for a unit under test.

9. The apparatus of claim 1, wherein the digital processor generates one or more sine wave values in real time.

10. A method for test equipment, wherein the method comprises:
receiving an analog test signal;
converting, by the analog-to-digital converter, the analog test signal to a digital test signal;
receiving, by a digital processor, the digital test signal;
processing, by the digital processor, the digital test signal;
storing, by a digital memory, the processed digital test signal;
receiving, by an digital-to-analog converter, the processed digital test signal; and
converting, by the digital-to-analog converter, the processed digital test signal to a processed analog test signal.
